(19) United States
(12) Patent Application Publication
(10) Pub. No.: US 2019/0058008 A1
(43) Pub. Date: Feb. 21, 2019

(54) SEMICONDUCTOR DEVICE

(71) Applicant: TOSHIBA MEMORY CORPORATION, Tokyo (JP)

(72) Inventors: Atsushi YAGISHITA, Kuwana Mie (JP); Masakazu GOTO, Yokkaichi Mie (JP); Kanna ADACHI, Chigasaki Kanagawa (JP)

(73) Assignee: TOSHIBA MEMORY CORPORATION, Tokyo (JP)

(21) Appl. No.: 15/909,392

(22) Filed: Mar. 1, 2018

(30) Foreign Application Priority Data
Aug. 18, 2017 (JP) 2017-158159

(51) Int. Cl. H01L 27/24; H01L 29/786; H01L 29/36; H01L 29/66; H01L 29/78

(52) U.S. Cl. CPC H01L 27/2454; H01L 29/78642; H01L 29/78606; H01L 29/36; H01L 29/45; H01L 29/78648; H01L 29/78618; H01L 29/7839; H01L 27/249; H01L 29/66742

(57) ABSTRACT

A semiconductor device includes a semiconductor layer, first gate electrode, second gate electrode, first conductive layer and second conductive layer. The semiconductor layer includes a first side surface, a second side surface, a first end portion, and a second end portion. The first side surface and the second side surface face each other. The first end portion and the second end portion face each other. A first gate insulating layer is provided between the first gate electrode and the first side surface. A second gate insulating layer is provided between the second gate electrode and the second side surface. A first metal oxide layer is provided between the first conductive layer and the first end portion. A second metal oxide layer is provided between the second conductive layer and the second end portion.

### CROSS-REFERENCE TO RELATED APPLICATION

This application claims the benefit of and priority to Japanese Patent Application No. 2017-158159, filed Aug. 18, 2017, the entire contents of which are incorporated herein by reference.

### FIELD

Embodiments described herein relate generally to a semiconductor device.

### BACKGROUND

In order to achieve high integration and three-dimensional structuring of a semiconductor integrated circuit, a vertical transistor is used. As miniaturization of the vertical transistor progresses, a device characteristic variation due to variations in processing or in impurity diffusion become problematic.

### DESCRIPTION OF THE DRAWINGS

FIG. 1 is a block diagram of a semiconductor device of a first embodiment.

FIG. 2 is an equivalent circuit diagram of a memory cell array of the first embodiment.

FIG. 3 is a schematic sectional view of a select transistor of the first embodiment.

FIG. 4 is a schematic perspective view of the select transistor of the first embodiment.

FIG. 5 is a schematic perspective view illustrating the semiconductor device during manufacturing in a manufacturing method of the semiconductor device of the first embodiment.

FIG. 6 is a schematic perspective view illustrating the semiconductor device during manufacturing in a manufacturing method of the semiconductor device of the first embodiment.

FIG. 7 is a schematic perspective view illustrating the semiconductor device during manufacturing in a manufacturing method of the semiconductor device of the first embodiment.

FIG. 8 is a schematic perspective view illustrating the semiconductor device during manufacturing in a manufacturing method of the semiconductor device of the first embodiment.

FIG. 9 is a schematic perspective view illustrating the semiconductor device during manufacturing in a manufacturing method of the semiconductor device of the first embodiment.

FIG. 10 is a schematic perspective view illustrating the semiconductor device during manufacturing in a manufacturing method of the semiconductor device of the first embodiment.

FIG. 11 is a schematic perspective view illustrating the semiconductor device during manufacturing in a manufacturing method of the semiconductor device of the first embodiment.

FIG. 12 is a schematic perspective view illustrating the semiconductor device during manufacturing in a manufacturing method of the semiconductor device of the first embodiment.

FIG. 13 is a schematic perspective view illustrating the semiconductor device during manufacturing in a manufacturing method of the semiconductor device of the first embodiment.

FIG. 14 is a schematic perspective view illustrating the semiconductor device during manufacturing in a manufacturing method of the semiconductor device of the first embodiment.

FIG. 15 is a schematic perspective view illustrating the semiconductor device during manufacturing in a manufacturing method of the semiconductor device of the first embodiment.

FIG. 16 is a schematic sectional view of a select transistor of a comparative embodiment.

FIG. 17 is a schematic sectional view of a select transistor of a second embodiment.

### DETAILED DESCRIPTION

Exemplary embodiments provide a semiconductor device having a vertical transistor capable of preventing a device characteristic variation.

In general, according to one embodiment, a semiconductor device comprises a semiconductor layer which includes a first side surface, a second side surface, a first end portion, and a second end portion, and in which the first side surface and the second side surface face each other, the first end portion and the second end portion face each other, and the first side surface and the second side surface are located between the first end portion and the second end portion; a first gate electrode; a second gate electrode; a first conductive layer; a second conductive layer; a first gate insulating layer that is provided between the first gate electrode and the first side surface; a second gate insulating layer that is provided between the second gate electrode and the second side surface; a first metal oxide layer that is provided between the first conductive layer and the first end portion; and a second metal oxide layer that is provided between the second conductive layer and the second end portion.

Hereinafter, exemplary embodiments will be described with reference to the drawings. Moreover, in the following description, the same reference numerals are given to the same or similar members, or the like, and description of a member once explained will be omitted as appropriate.

Qualitative analysis and quantitative analysis of a chemical composition of a member configuring a semiconductor device in the present specification can be carried out by a Secondary Ion Mass Spectroscopy (SIMS) and an Energy Dispersive X-ray Spectroscopy (EDX). In addition, a thickness of a member, a distance between members configuring the semiconductor device, or the like can be measured by using, for example, a Transmission Electron Microscope (TEM). In addition, stress of a member configuring the semiconductor device can be carried out by using, for example, a Raman spectroscopy.

Hereinafter, a storage device of some embodiments is described with reference to the drawings.

### First Embodiment

A semiconductor device of some embodiments include a semiconductor layer which includes a first side surface, a second side surface, a first end portion, and a second end portion, and in which the first side surface and the second side surface face each other, the first end portion and the second end portion face each other, and the first side surface and the second side surface are located between the first end portion and the second end portion; a first gate electrode; a second gate electrode; a first conductive layer; a second conductive layer; a first gate insulating layer that is provided between the first gate electrode and the first side surface; a second gate insulating layer that is provided between the second gate electrode and the second side surface; a first metal oxide layer that is provided between the first conductive layer and the first end portion; and a second metal oxide layer that is provided between the second conductive layer and the second end portion.

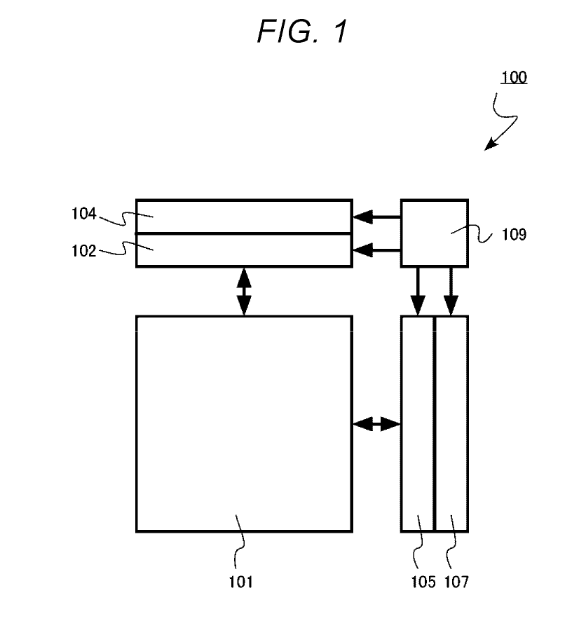

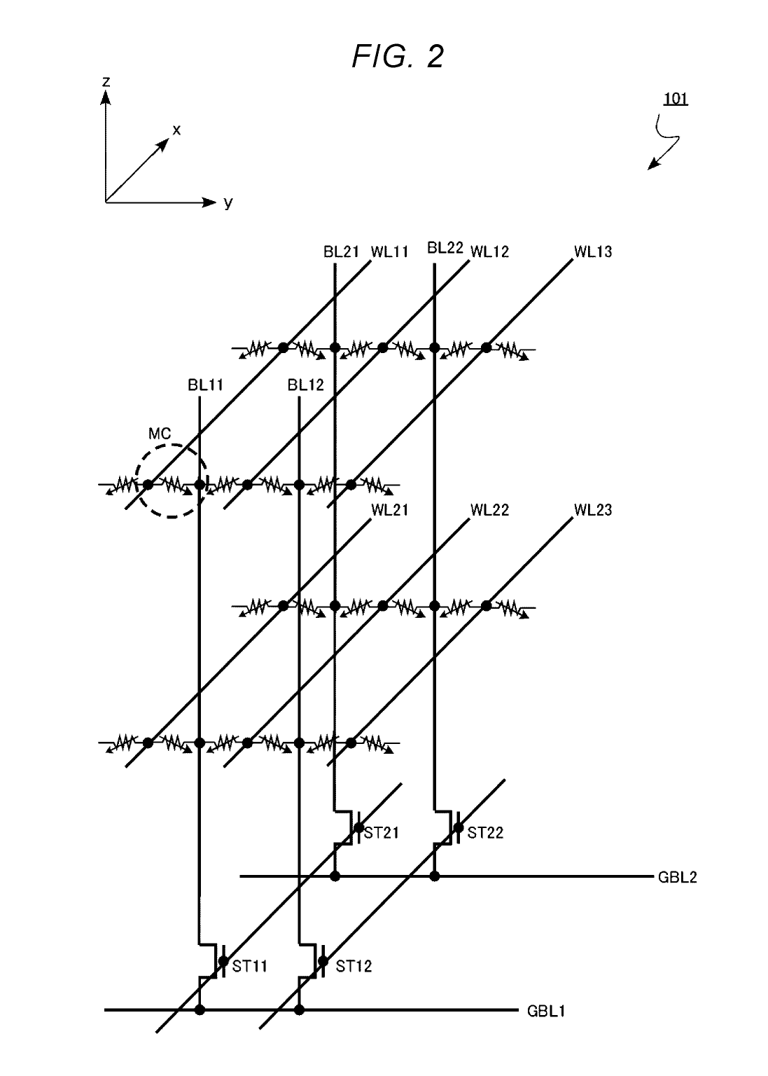

FIG. 1 is a block diagram of the semiconductor device of the first embodiment. FIG. 2 is an equivalent circuit diagram of a memory cell array. FIG. 2 schematically illustrates a wiring structure in the memory cell array.

The semiconductor device of the embodiment is a resistance-variable type memory 100. The resistance-variable type memory 100 stores data using a resistance variation of a variable resistance layer.

In addition, a memory cell array of the resistance-variable type memory 100 includes a three-dimensional structure in which memory cells MC are three-dimensionally arranged. A degree of integration of the resistance-variable type memory 100 is improved by providing the three-dimensional structure.

As illustrated in FIG. 1, the resistance-variable type memory 100 includes a memory cell array 101, a word line driver circuit 102, a row decoder circuit 104, a sense amplifier circuit 105, a column decoder circuit 107, and a control circuit 109.

In addition, as illustrated in FIG. 2, a plurality of the memory cells MC are three-dimensionally arranged in the memory cell array 101. In FIG. 2, a region surrounded by a broken line corresponds to one memory cell MC.

The memory cell array 101 includes, for example, a plurality of word lines WL (WL11, WL12, WL13, WL21, WL22, and WL23) and a plurality of bit lines BL (BL11, BL12, BL21, and BL22). The word line WL extends in an x direction. The bit line BL extends in a z direction. The word line WL and the bit line BL intersect perpendicularly. The memory cell MC is disposed at an intersection of the word line WL and the bit line BL.

The plurality of the word lines WL are electrically connected to the row decoder circuit 104. The plurality of the bit lines BL are electrically connected to the sense amplifier circuit 105. Select transistors ST (ST11, ST21, ST12, and ST22) and global bit lines GBL (GBL1 and GBL2) are provided between the plurality of the bit lines BL and the sense amplifier circuit 105.

The row decoder circuit 104 includes a function of selecting a word line WL according to an input row address signal. The word line driver circuit 102 includes a function of applying a predetermined voltage to a word line WL selected by the row decoder circuit 104.

The column decoder circuit 107 includes a function of selecting a bit line BL according to an input column address signal. The sense amplifier circuit 105 includes a function of applying a predetermined voltage to a bit line BL selected by the column decoder circuit 107. In addition, the sense amplifier circuit 105 includes a function of detecting and amplifying a current flowing between the selected word line WL and the selected bit line BL.

The control circuit 109 includes a function of controlling the word line driver circuit 102, the row decoder circuit 104, the sense amplifier circuit 105, the column decoder circuit 107, and other circuits (not illustrated).

Circuits such as the word line driver circuit 102, the row decoder circuit 104, the sense amplifier circuit 105, the column decoder circuit 107, and the control circuit 109 may be configured with, for example, a transistor or a wiring layer using a semiconductor layer (not illustrated).

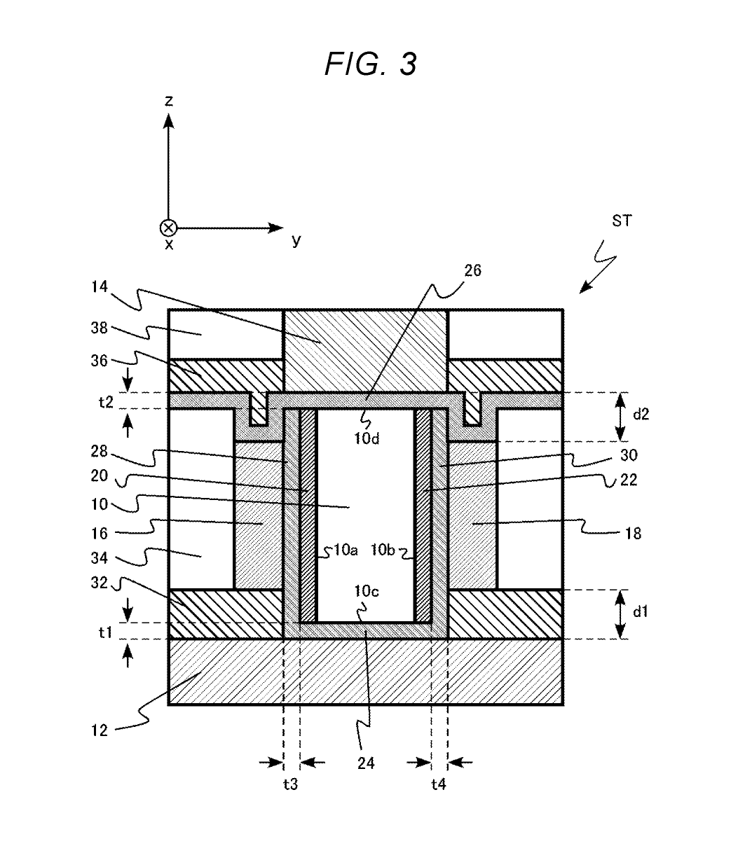

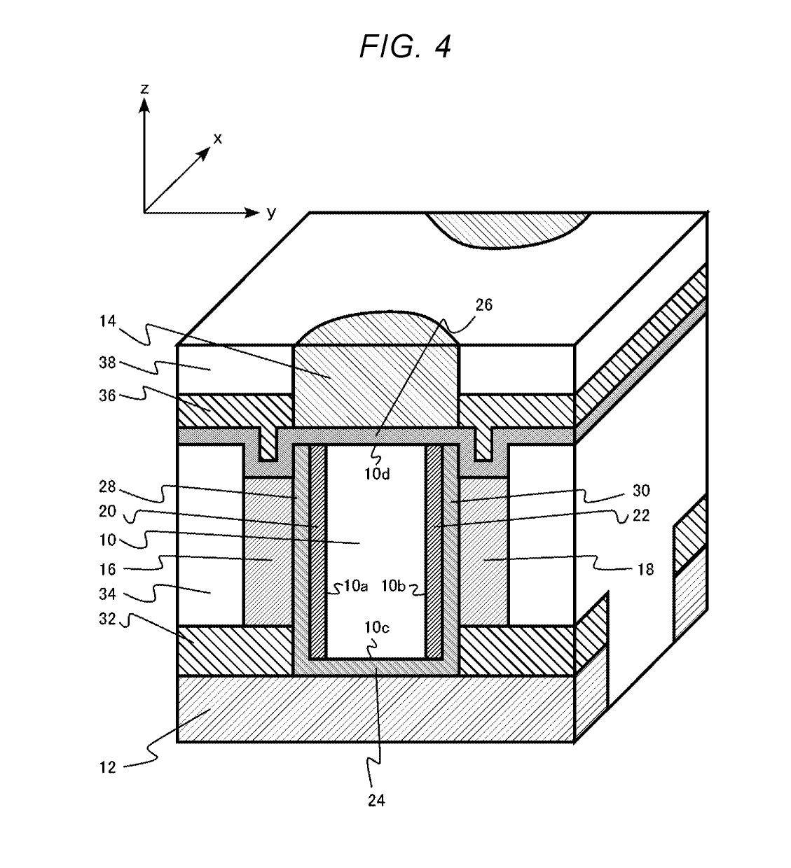

FIG. 3 is a schematic sectional view of the select transistor ST of the embodiment. FIG. 3 illustrates a sectional view of an yz plane. FIG. 4 is a schematic perspective view of the select transistor ST of the embodiment. The select transistor ST is a vertical thin film transistor (TFT). In addition, the select transistor ST is a Schottky junction transistor in which a source electrode and a drain electrode are Schottky-junctioned to a channel region. In addition, the select transistor ST is an n-channel transistor using electrons as a carrier.

The select transistor ST includes a semiconductor layer 10, a source electrode 12 (first conductive layer), a drain electrode 14 (second conductive layer), a first gate electrode 16, a second gate electrode 18, a first gate insulating layer 20, a second gate insulating layer 22, a first barrier control layer 24 (first metal oxide layer), a second barrier control layer 26 (second metal oxide layer), a first threshold control layer 28 (third metal oxide layer), a second threshold control layer 30 (fourth metal oxide layer), a first interlayer insulating layer 32, a second interlayer insulating layer 34, a third interlayer insulating layer 36, and a fourth interlayer insulating layer 38.

The semiconductor layer 10 includes a first side surface 10a, a second side surface 10b, a first end portion 10c, and a second end portion 10d. The first side surface 10a and the second side surface 10b face each other, and the first end portion 10c and the second end portion 10d face each other. The first side surface 10a and the second side surface 10b are located between the first end portion 10c and the second end portion 10d. The semiconductor layer 10 functions as a channel region of the select transistor ST.

The semiconductor layer 10 may be, for example, polycrystalline silicon. The semiconductor layer 10 may be, for example, polycrystalline germanium or polycrystalline silicon germanide. In addition, the semiconductor layer 10 may be a single crystal.

The semiconductor layer 10 may be, for example, a p-type semiconductor including a p-type impurity as a conductive impurity. The p-type impurity may be, for example, boron (B). An impurity concentration of the p-type impurity in the semiconductor layer 10 may be, for example, 1×10¹⁷ atoms/cm³ or less.

The semiconductor layer 10 may be an intrinsic semiconductor. The intrinsic semiconductor is a semiconductor in which a conductive impurity is not positively introduced. In a case of the intrinsic semiconductor, a conductive impurity concentration in the semiconductor layer 10 may be, for example, 1×10¹⁵ atoms/cm³. The semiconductor layer 10 may be an n-type semiconductor including an n-type impurity as a conductive impurity. The concentration of the conductive impurity in the semiconductor layer 10 is substantially uniform.

A thickness of the semiconductor layer 10 in the y direction may be, for example, greater than or equal to 5 nm and less than or equal to 25 nm.

The source electrode 12 is provided on a side of the first end portion 10c of the semiconductor layer 10. The source electrode 12 is the global bit line GBL of the resistance-variable type memory 100.

The source electrode 12 may be, for example, a metal or a metal semiconductor compound. The source electrode 12 is, for example, a stacked structure of titanium nitride (TiN) and tungsten (W). For example, titanium nitride (TiN) is provided between tungsten (W) and the first end portion 10c. The source electrode 12 is, for example, metal silicide. The source electrode 12 is, for example, erbium silicide, nickel silicide, or cobalt silicide.

The drain electrode 14 may be provided on a side of the second end portion 10d of the semiconductor layer 10. The drain electrode 14 is electrically connected to the bit line BL of the resistance-variable type memory 100.

The drain electrode 14 is, for example, a metal or a metal semiconductor compound. The drain electrode 14 may be, for example, a stacked structure of titanium nitride (TiN) and tungsten (W). For example, titanium nitride (TiN) is provided between tungsten (W) and the second end portion 10d. The drain electrode 14 may be, for example, metal silicide. The drain electrode 14 is, for example, erbium silicide, nickel silicide, or cobalt silicide.

The first gate electrode 16 is provided on a side of the first side surface 10a of the semiconductor layer 10. The first gate electrode 16 may be, for example, a metal, a metal semiconductor compound, or a semiconductor. The first gate electrode 16 may be, for example, titanium nitride (TiN).

The second gate electrode 18 is provided on a side of the second side surface 10b of the semiconductor layer 10. The second gate electrode 18 may be, for example, a metal, a metal semiconductor compound, or a semiconductor. The second gate electrode 18 may be, for example, titanium nitride (TiN).

The first gate electrode 16 and the second gate electrode 18 are electrically connected. The same gate voltage is applied to the first gate electrode 16 and the second gate electrode 18. The first gate electrode 16 and the second gate electrode 18 may be physically connected or physically separated.

The first gate electrode 16 and the source electrode 12 are separated by a distance d1 in a direction (z direction) connecting the first end portion 10c and the second end portion 10d. The second gate electrode 18 and the source electrode 12 are separated by the distance d1 in the direction (z direction) connecting the first end portion 10c and the second end portion 10d.

The first gate electrode 16 and the drain electrode 14 are separated by a distance d2 in the direction (z direction) connecting the first end portion 10c and the second end portion 10d. The second gate electrode 18 and the drain electrode 14 are separated by the distance d2 in the direction (z direction) connecting the first end portion 10c and the second end portion 10d.

The first gate insulating layer 20 is provided between the first gate electrode 16 and the first side surface 10a of the semiconductor layer 10. The first gate insulating layer 20 is provided in contact with the first side surface 10a.

The first gate insulating layer 20 may be an oxide or an oxynitride. The first gate insulating layer 20 includes at least one substance selected from the group consisting of, for example, hafnium oxide, hafnium silicate, and nitrogen-added hafnium silicate.

The second gate insulating layer 22 is provided between the second gate electrode 18 and the second side surface 10b of the semiconductor layer 10. The second gate insulating layer 22 is provided in contact with the second side surface 10b.

The second gate insulating layer 22 may be an oxide or an oxynitride. The second gate insulating layer 22 includes at least one substance selected from the group consisting of, for example, hafnium oxide, hafnium silicate, and nitrogen-added hafnium silicate.

The first barrier control layer 24 is provided between the source electrode 12 and the first end portion 10c of the semiconductor layer 10. The first barrier control layer 24 is provided in contact with the first end portion 10c and the source electrode 12.

The first barrier control layer 24 has a dipole. The first barrier control layer 24 has a function of reducing a height of the Schottky barrier between the semiconductor layer 10 and the source electrode 12.

The second barrier control layer 26 is provided between the drain electrode 14 and the second end portion 10d of the semiconductor layer 10. The second barrier control layer 26 is provided in contact with the second end portion 10d and the drain electrode 14.

The second barrier control layer 26 has a dipole. The second barrier control layer 26 has a function of reducing a height of the Schottky barrier between the semiconductor layer 10 and the drain electrode 14.

The first barrier control layer 24 and the second barrier control layer 26 may include an oxide of at least one metal element selected from the group consisting of rare earth elements (scandium (Sc), yttrium (Y), lanthanum (La), cerium (Ce), praseodymium (Pr), neodymium (Nd), Promethium (Pm), Samarium (Sm), europium (Eu), gadolinium (Gd), terbium (tb), dysprosium (Dy), holmium (Ho), erbium (Er), thulium (Tm), ytterbium (Yb), and lutetium (Lu)), zinc (Zn), and magnesium (Mg). The first barrier control layer 24 and the second barrier control layer 26 may be, for example, lanthanum oxide (La₂O₃).

A thickness (t1 in FIG. 3) of the first barrier control layer 24 and a thickness (t2 in FIG. 3) of the second barrier control layer 26 are, for example, greater than or equal to 0.2 nm and less than or equal to 1.5 nm.

The first threshold control layer 28 is provided between the first gate electrode 16 and the first gate insulating layer 20. The first threshold control layer 28 is provided in contact with the first gate electrode 16 and the first gate insulating layer 20.

The first threshold control layer 28 has a dipole. The first threshold control layer 28 has a function of reducing a threshold voltage of the select transistor ST.

The second threshold control layer 30 is provided between the second gate electrode 18 and the second gate insulating layer 22. The second threshold control layer 30 is provided in contact with the second gate electrode 18 and the second gate insulating layer 22.

The second threshold control layer 30 has a dipole. The second threshold control layer 30 has a function of reducing a threshold voltage of the select transistor ST.

The first threshold control layer 28 and the second threshold control layer 30 may include an oxide of at least one metal element selected from the group consisting of rare earth elements (scandium (Sc), yttrium (Y), lanthanum (La), cerium (Ce), praseodymium (Pr), neodymium (Nd), Promethium (Pm), Samarium (Sm), europium (Eu), gadolinium (Gd), terbium (tb), dysprosium (Dy), holmium (Ho), erbium (Er), thulium (Tm), ytterbium (Yb), and lutetium (Lu)), zinc (Zn), and magnesium (Mg). The first threshold control layer 28 and the second threshold control layer 30 may be, for example, lanthanum oxide (La₂O₃).

A thickness (t3 in FIG. 3) of the first threshold control layer 28 and a thickness (t4 in FIG. 3) of the second threshold control layer 30 may be, for example, greater than or equal to 0.2 nm and less than or equal to 1.5 nm. The thickness (t1 in FIG. 3) of the first barrier control layer 24 and the thickness (t2 in FIG. 3) of the second barrier control layer 26 may be, for example, thicker than the thickness (t3 in FIG. 3) of the first threshold control layer 28 and the thickness (t4 in FIG. 3) of the second threshold control layer 30.

The first interlayer insulating layer 32 may be, for example, silicon nitride. In addition, the second interlayer insulating layer 34 may be, for example, silicon oxide. In addition, the third interlayer insulating layer 36 may be, for example, silicon nitride. In addition, the fourth interlayer insulating layer 38 may be, for example, silicon oxide.

Next, an example of a manufacturing method of the semiconductor device of some embodiments will be described.

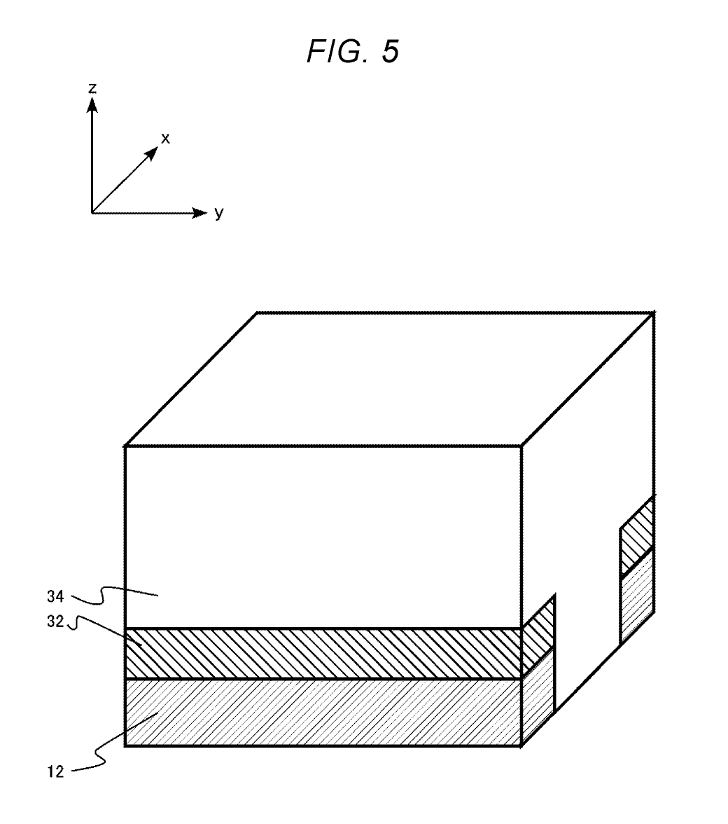

FIGS. 5 to 15 are schematic perspective views illustrating the semiconductor device during manufacturing in a manufacturing method of the semiconductor device of some embodiments. FIGS. 5 to 15 illustrate an example of the manufacturing method of the select transistor ST of some embodiments.

First, a stacked film of tungsten and titanium nitride, and a silicon nitride film are formed by a chemical vapor deposition (CVD) method. Next, the source electrode 12 and the first interlayer insulating layer 32 are formed by patterning by a lithography method and a dry etching method. The source electrode 12 is the global bit line GBL of the resistance-variable type memory 100. Next, for example, a silicon oxide film may be stacked by the CVD method to form the second interlayer insulating layer 34 (FIG. 5).

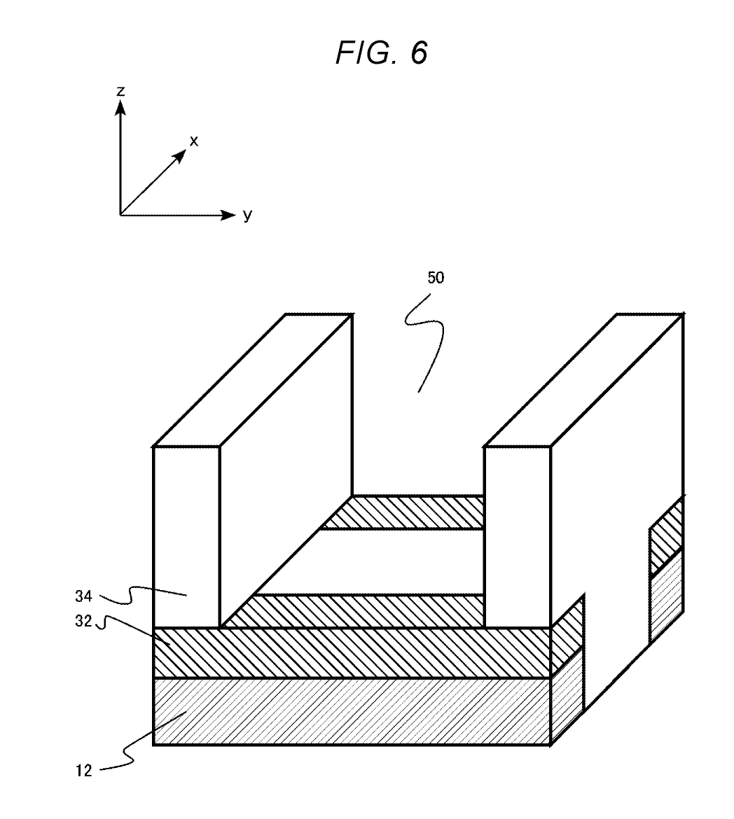

Next, a groove 50 for forming a gate electrode structure is formed by patterning by the lithography method and the dry etching method (FIG. 6).

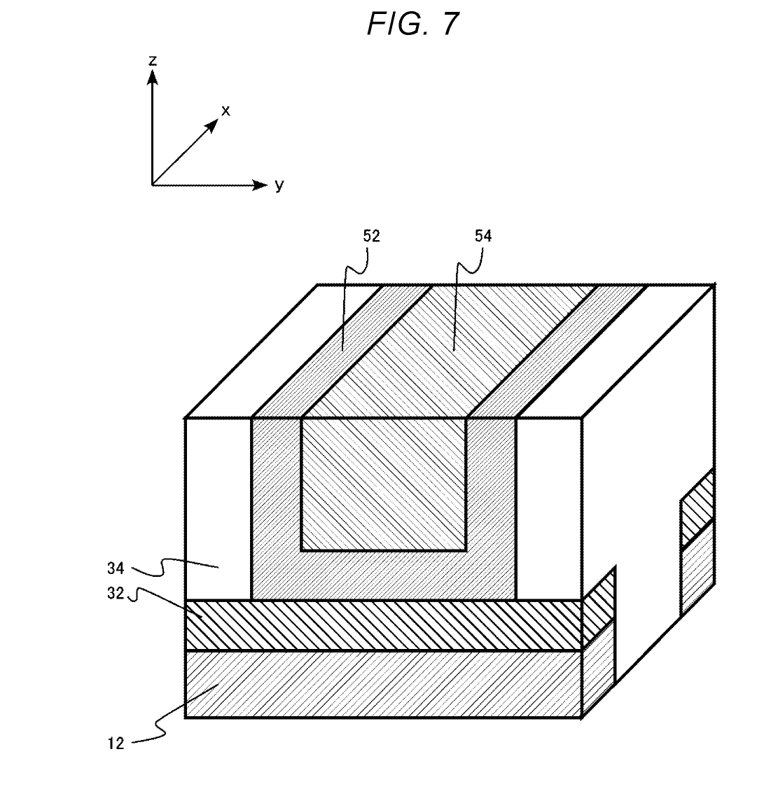

Next, a titanium nitride film 52 and an amorphous silicon germanide film 54 are formed in the groove 50 by the CVD method and are flattened by a chemical mechanical polishing method (CMP method) (FIG. 7).

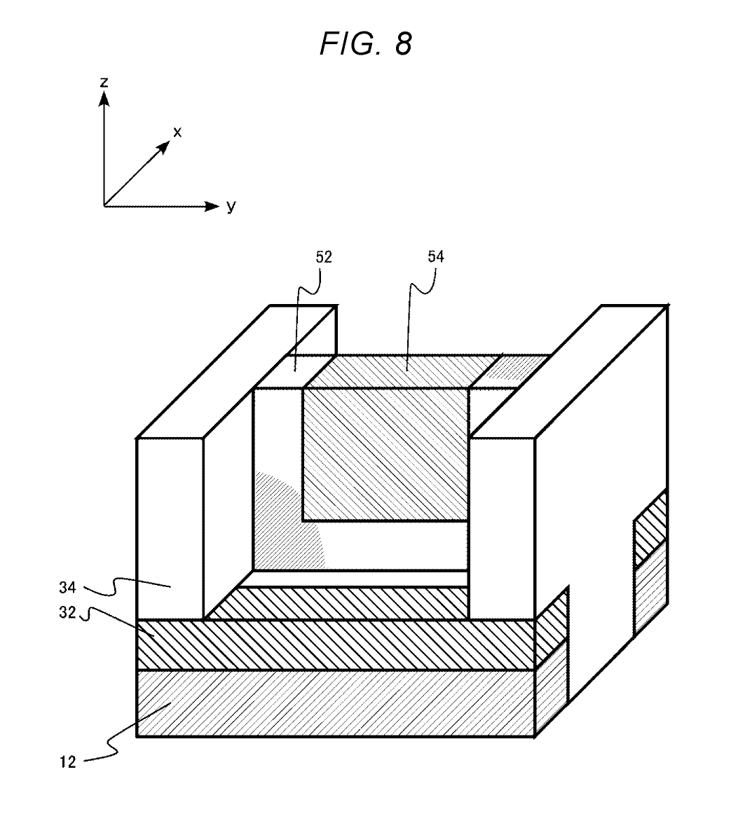

Next, the titanium nitride film 52 and the amorphous silicon germanide film 54 are patterned by the lithography method and the dry etching method (FIG. 8).

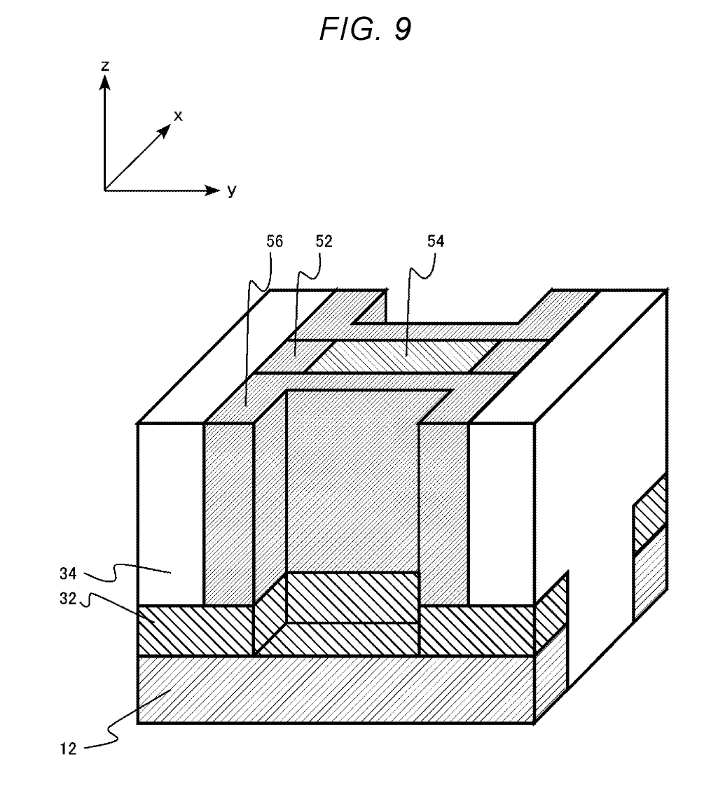

Next, a titanium nitride film 56 is deposited by the CVD method and then a bottom portion of the titanium nitride film 56 is selectively removed by the dry etching method. Thereafter, a part of the first interlayer insulating layer 32 is removed by the dry etching method (FIG. 9).

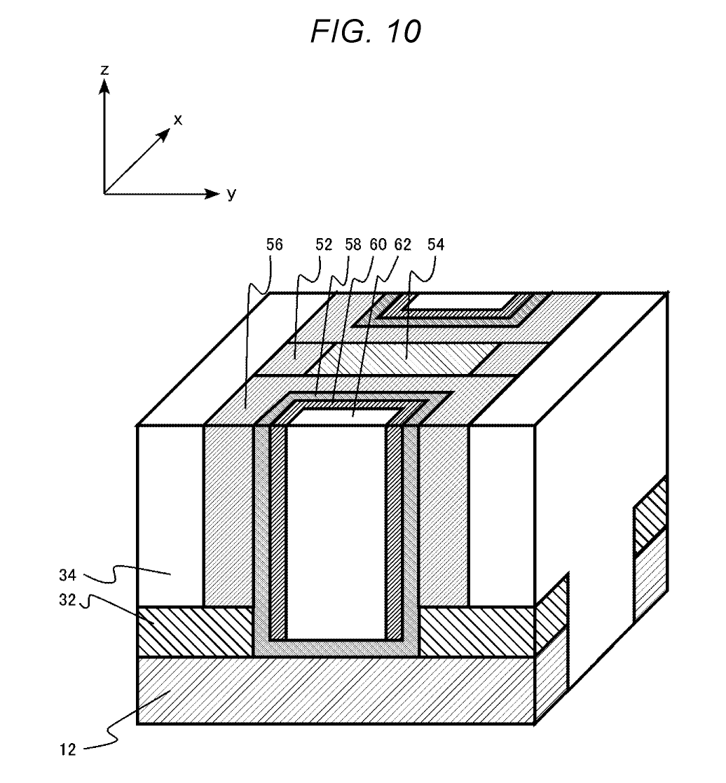

Next, a lanthanum oxide film 58 and a hafnium oxide film 60 are deposited by an atomic layer deposition method (ALD method). Thereafter, a bottom portion of the hafnium oxide film 60 is selectively removed by the dry etching method. Thereafter, a polycrystalline silicon film 62 is deposited by the CVD method. Thereafter, the polycrystalline silicon film 62 is flattened by the CMP method (FIG. 10).

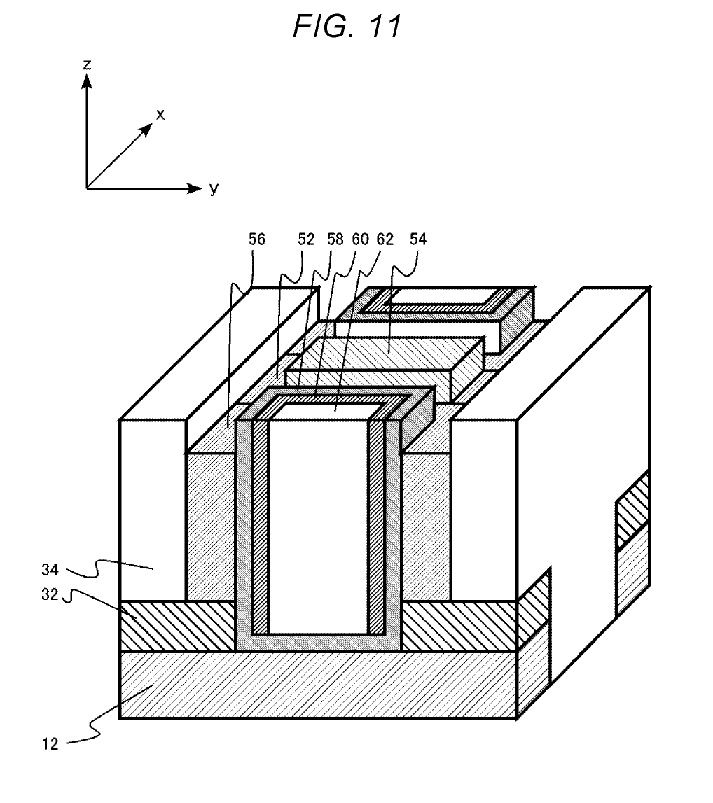

Next, the titanium nitride film 52 and the titanium nitride film 56 are etched back by the dry etching method (FIG. 11).

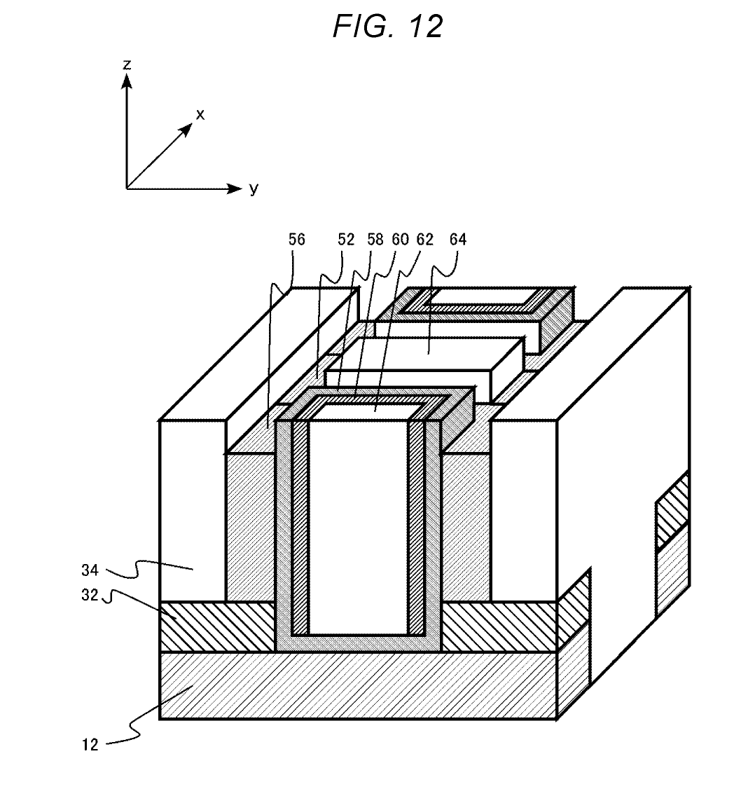

Next, an upper portion of the amorphous silicon germanide film 54 is oxidized to form an oxide layer 64 (FIG. 12). An oxidation rate of the amorphous silicon germanide film 54 is faster than an oxidation rate of the polycrystalline silicon film 62.

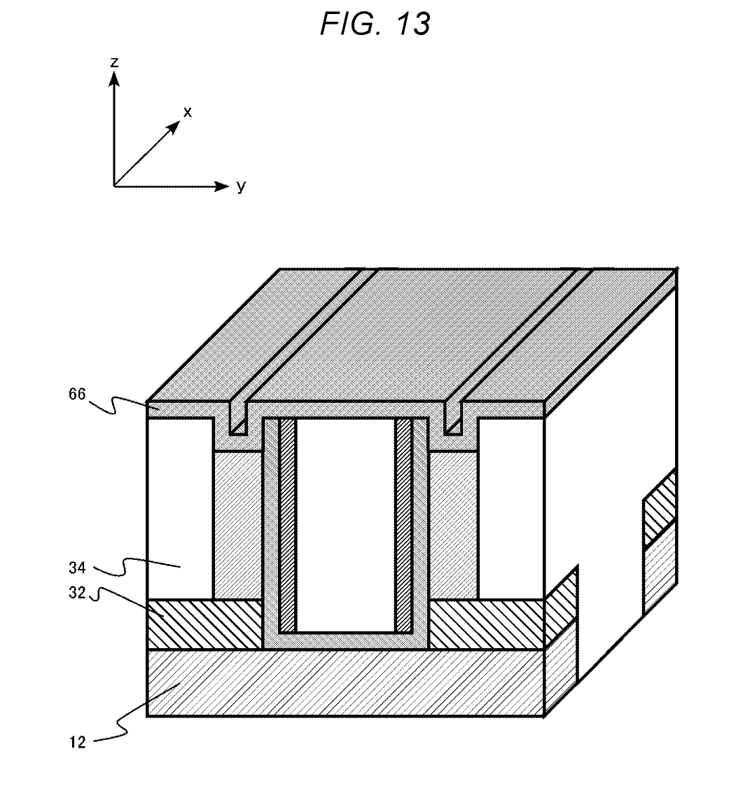

Next, a lanthanum oxide film 66 is deposited by the ALD method (FIG. 13).

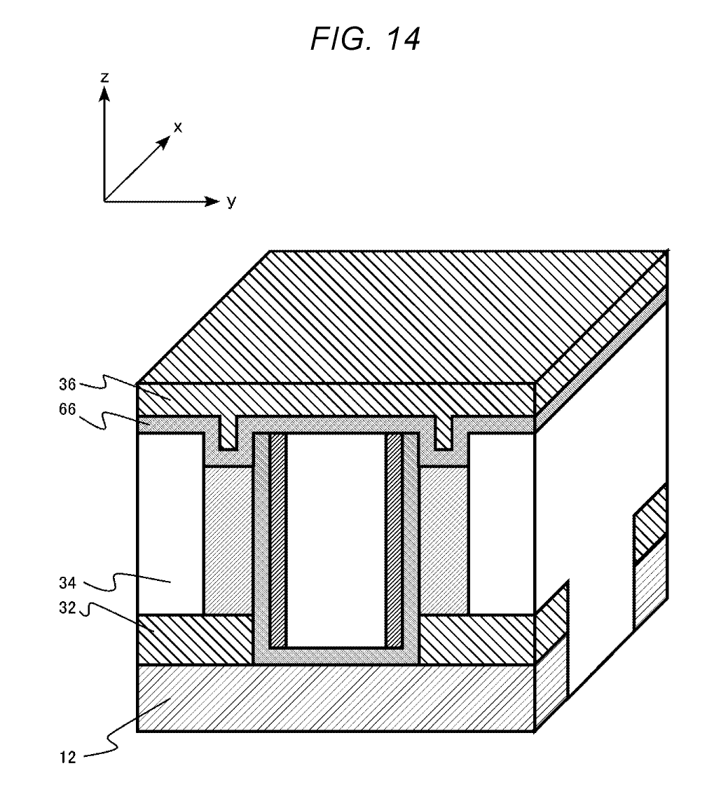

Next, a silicon nitride film is deposited by the ALD method to form the third interlayer insulating layer 36 (FIG. 14).

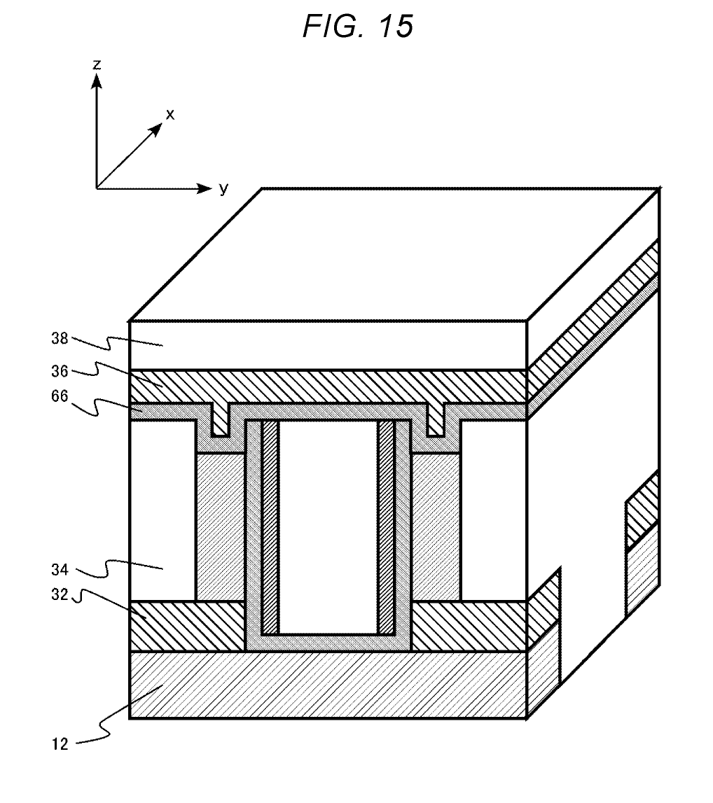

Next, a silicon oxide film is deposited by the CVD method to form the fourth interlayer insulating layer 38 (FIG. 15).

Next, a contact hole is formed by the lithography method and the dry etching method, a titanium nitride film and a tungsten film are embedded by the CVD method, and then are flattened to form the drain electrode 14 by the CMP method.

The select transistor ST of embodiments illustrated in FIGS. 3 and 4 may be manufactured by the manufacturing method described above.

Next, operations and effects of the semiconductor device and the manufacturing method of a semiconductor device of the embodiment will be described.

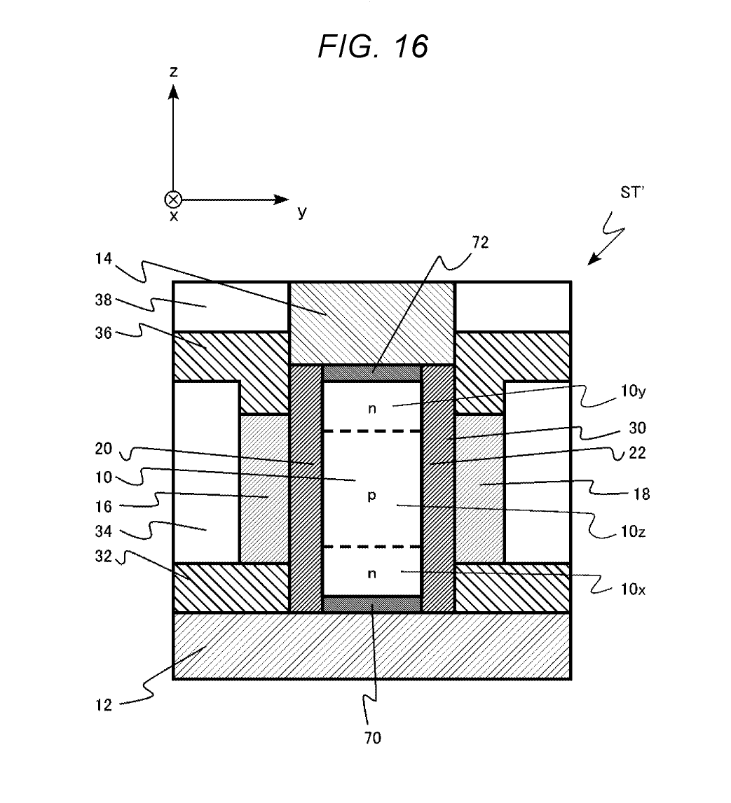

FIG. 16 is a schematic sectional view of a select transistor ST′ of a comparative embodiment. The select transistor ST′ of the comparative embodiment is a vertical TFT.

The select transistor ST′ of the comparative embodiment is different from the select transistor ST of the embodiment in that the semiconductor layer 10 includes an n-type source region 10x, an n-type drain region 10y, and a p-type channel region 10z. In addition, it is different in that a first silicide layer 70 is provided between the source region 10x and the source electrode 12 to reduce a contact resistance. In addition, it is different in that a second silicide layer 72 is provided between the drain region 10y and the drain electrode 14 to reduce the contact resistance. Furthermore, the select transistor ST′ of the comparative embodiment does not include the first barrier control layer 24, the second barrier control layer 26, the first threshold control layer 28, and the second threshold control layer 30.

In the select transistor ST′ of the comparative embodiment, the first gate electrode 16 and the second gate electrode 18 overlap the source region 10x in the z direction. In addition, the first gate electrode 16 and the second gate electrode 18 overlap the drain region 10y in the z direction. An overlap amount between the first gate electrode 16, the second gate electrode 18, and the source region 10x in the z direction is changed by a positional variation between the first gate electrode 16 and the second gate electrode 18 in the z direction, and a variation in a diffusion profile of an n-type impurity of the source region 10x. Similarly, an overlap amount between the first gate electrode 16, the second gate electrode 18, and the drain region 10y in the z direction is changed by the positional variation between the first gate electrode 16 and the second gate electrode 18 in the z direction, and a variation in a diffusion profile of an n-type impurity of the drain region 10y.

When the overlap amount in the z direction varies, a transistor characteristic of the select transistor ST′ varies. Specifically, an off-current due to a gate induced drain leakage (GIDL) varies. For example, when the overlap amount in the z direction increases, the GIDL increases, and the off-current increases. In addition, for example, when an offset occurs in the first gate electrode 16, the second gate electrode 18, and the drain region 10y in the z direction, a decrease in an on-current becomes large.

In addition, in the select transistor ST′ of the comparative embodiment, if the diffusion profile of the n-type impurity of the source region 10x or the n-type impurity of the drain region 10y varies, a length of the channel region 10z in the z direction, that is, a channel length varies. Therefore, the on-current and the off-current of the select transistor ST′ vary.

In addition, in the select transistor ST′ of the comparative embodiment, there is a concern that a variation of a threshold voltage is increased by random dopant fluctuation (RDF) of the p-type impurity of the channel region 10z.

In addition, an interface between the first silicide layer 70 and the semiconductor layer 10, and an interface between the second silicide layer 72 and the semiconductor layer 10 is in an irregular shape as a result of a silicidation reaction. When the irregular shape varies, the on-current or the off-current varies.

An accuracy requirement for the characteristic variation of the select transistor is more severe with the miniaturization of the select transistor.

The select transistor ST of the embodiment is a Schottky junction transistor. In a case of the Schottky junction transistor, for example, there is a problem that a height of the Schottky barrier between the source electrode 12 and the semiconductor layer 10, or a height of the Schottky barrier between the drain electrode 14 and the semiconductor layer 10 cannot be reduced due to an influence of Fermi level pinning. Therefore, there is a problem that the on-resistance cannot be reduced.

In the select transistor ST of the embodiment, the first barrier control layer 24 is provided between the source electrode 12 and the semiconductor layer 10. The first barrier control layer 24 has the dipole so that it is possible to reduce the height of the Schottky barrier between the source electrode 12 and the semiconductor layer 10. Similarly, the second barrier control layer 26 is provided so that it is possible to reduce the height of the Schottky barrier between the drain electrode 14 and the semiconductor layer 10. Therefore, the on-resistance of the select transistor ST can be reduced and the on-current can be increased.

The thickness (t1 in FIG. 3) of the first barrier control layer 24 and the thickness (t2 in FIG. 3) of the second barrier control layer 26 may be, for example, preferably greater than or equal to 0.2 nm and less than or equal to 1.5 nm, and more preferably greater than or equal to 0.6 nm and less than or equal to 1.0 nm. If it is below the range, there is a concern that a size of the dipole is insufficient and the height of the Schottky barrier is not sufficiently low. If it is above the range, there is a concern that the on-resistance increases due to the resistance of the first barrier control layer 24 and the second barrier control layer 26. In addition, from the viewpoint of maximizing the size of the dipole, the thickness is preferably greater than or equal to 0.6 nm and less than or equal to 1.0 nm.

In addition, in the interface between the first barrier control layer 24 and the semiconductor layer 10, and the interface between the second barrier control layer 26 and the semiconductor layer 10, since the reaction does not proceed, the interface has a flat shape. Therefore, since the variation in shape is small, the variation in the on-current and the off-current is reduced.

In addition, since the select transistor ST of the embodiment is a Schottky junction transistor, there is no need to provide a pn junction in the semiconductor layer 10. The concentration of the conductive impurity of the semiconductor layer 10 can be substantially uniform. Therefore, the variation in the on-current or the off-current due to the variation of the diffusion profile of the conductive impurity such as the select transistor ST′ of the comparative embodiment is reduced.

From the viewpoint of reducing the characteristic variation due to the variation in the diffusion profile of the conductive impurity or the characteristic variation due to the RDF, the semiconductor layer 10 is preferably an intrinsic semiconductor. From the viewpoint of reducing the characteristic variation due to the variation in the diffusion profile of the conductive impurity or the characteristic variation due to the RDF, the concentration of the conductive impurity of the semiconductor layer 10 is preferably less than or equal to 1×10¹⁵ atoms/cm³.

In addition, the first gate electrode 16, the second gate electrode 18, and the source electrode 12 are separated in the z direction and do not overlap each other. Similarly, the first gate electrode 16, the second gate electrode 18, and the drain electrode 14 are separated in the z direction and do not overlap each other. Therefore, there is no variation in the off-current due to the variation in the overlap amount. In addition, the off-current due to the GIDL is also reduced.

From the viewpoint of increasing the on-current of the select transistor ST, the separation distance d1 between the first gate electrode 16 and the source electrode 12 in the z direction is preferably minimized within a range in which a breakdown voltage between the first gate electrode 16 and the source electrode 12 can be maintained. Similarly, the separation distance d1 between the second gate electrode 18 and the source electrode 12 in the z direction is preferably minimized within a range in which a breakdown voltage between the second gate electrode 18 and the source electrode 12 can be maintained. Similarly, the separation distance d2 between the first gate electrode 16 and the drain electrode 14 in the z direction is preferably minimized within a range in which a breakdown voltage between the first gate electrode 16 and the drain electrode 14 can be maintained. Similarly, the separation distance d2 between the second gate electrode 18 and the drain electrode 14 in the z direction is preferably minimized within a range in which a breakdown voltage between the second gate electrode 18 and the drain electrode 14 can be maintained.

In addition, the select transistor ST of some embodiments includes the first threshold control layer 28 and the second threshold control layer 30 so that it is possible to reduce the threshold voltage. Therefore, it is possible to increase the on-current of the select transistor ST.

Moreover, the first barrier control layer 24, the first threshold control layer 28, and the second threshold control layer 30 can be simultaneously formed according to the manufacturing method of the embodiment. Therefore, it is possible to prevent an increase in the manufacturing cost.

The thickness (t3 in FIG. 3) of the first threshold control layer 28 and the thickness (t4 in FIG. 3) of the second threshold control layer 30 are preferably greater than or equal to 0.2 nm and less than or equal to 1.5 nm, and more preferably greater than or equal to 0.2 nm and less than or equal to 0.6 nm. If it is below the range, there is a concern that the size of the dipole is insufficient and the threshold voltage is not sufficiently low. If it is above the range, there is a concern that the threshold voltage is too low. In addition, from the viewpoint of maximizing the threshold voltage, the thickness is preferably greater than or equal to 0.2 nm and less than or equal to 0.6 nm.

Optimum values of the thickness (t3 in FIG. 3) of the first threshold control layer 28 and the thickness (t4 in FIG. 3) of the second threshold control layer 30 are different from optimum values of the thickness (t1 in FIG. 3) of the first barrier control layer 24 and the thickness (t2 in FIG. 3) of the second barrier control layer 26. From the viewpoint of optimizing thereof, the thickness (t1 in FIG. 3) of the first barrier control layer 24 and the thickness (t2 in FIG. 3) of the second barrier control layer 26 are preferably thicker than the thickness (t3 in FIG. 3) of the first threshold control layer 28 and the thickness (t4 in FIG. 3) of the second threshold control layer 30.

As described above, according to some embodiments, a semiconductor device including a vertical transistor, in which the variation in the device characteristic can be reduced, the on-current is increased, and the off-current is decreased, can be achieved.

### Second Embodiment

A semiconductor device of the second embodiment is different from the first embodiment in that a semiconductor layer has a tensile stress in a direction in which a first end portion and a second end portion are connected. Hereinafter, description of contents overlapping with the first embodiment will be omitted.

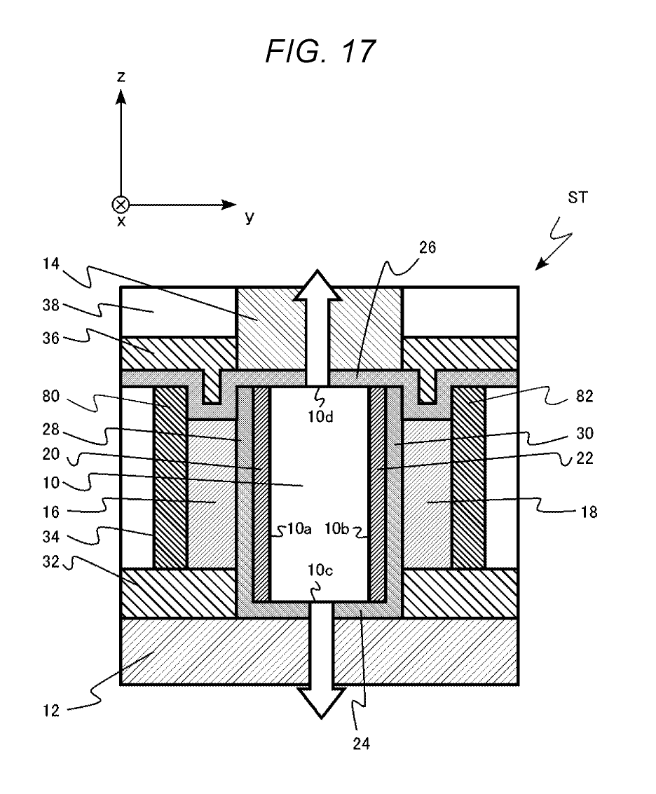

FIG. 17 is a schematic sectional view of a select transistor ST of the second embodiment. FIG. 17 illustrates a sectional view of an yz plane. The select transistor ST is a vertical TFT. In addition, the select transistor ST is a Schottky junction transistor in which a source electrode and a drain electrode are Schottky-junctioned to a channel region. In addition, the select transistor ST is an n-channel transistor using electrons as a carrier.

The select transistor ST includes a semiconductor layer 10, a source electrode 12 (first conductive layer), a drain electrode 14 (second conductive layer), a first gate electrode 16, a second gate electrode 18, a first gate insulating layer 20, a second gate insulating layer 22, a first barrier control layer 24 (first metal oxide layer), a second barrier control layer 26 (second metal oxide layer), a first threshold control layer 28 (third metal oxide layer), a second threshold control layer 30 (fourth metal oxide layer), a first interlayer insulating layer 32, a second interlayer insulating layer 34, a third interlayer insulating layer 36, a fourth interlayer insulating layer 38, a first stress liner layer 80 (first insulating layer), and a second stress liner layer 82 (second insulating layer).

The first stress liner layer 80 and the second stress liner layer 82 may be, for example, compression (expansion) silicon nitride. The first stress liner layer 80 and the second stress liner layer 82 function as a compressive stress liner film.

As the first stress liner layer 80 and the second stress liner layer 82 are expanded to compress the semiconductor layer 10, the semiconductor layer 10 includes a uniaxial tensile stress in a direction (z direction) in which the first end portion 10c and the second end portion 10d are connected. An energy level of a lower end of the semiconductor of the semiconductor layer 10 decreases with the tensile stress. Therefore, a height of the Schottky barrier between the semiconductor layer 10 and the source electrode 12, and a height of the Schottky barrier between the semiconductor layer 10 and the drain electrode 14 are reduced. In addition, the mobility of electrons increases. Therefore, the on-resistance is decreased and the on-current is increased of the select transistor ST.

As described above, according to the embodiment, the semiconductor device including the vertical transistor in which the on-current is further increased in addition to the effects of the first embodiment.

In the first and second embodiments, as the semiconductor device, a case of the resistance-variable type memory is described as an example, but the vertical transistor of the first and second embodiments can also be applied to a semiconductor device other than the resistance-variable type memory. For example, the vertical transistor of the first and second embodiments can be applied to a semiconductor memory other than the resistance-variable type memory. In addition, for example, the vertical transistor of the first and second embodiments can also be applied as a transistor connecting a logic circuit of a logic device.

While certain embodiments have been described, these embodiments have been presented byway of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor layer which includes a first side surface, a second side surface facing the first side surface, a first end portion, and a second end portion facing the first end portion, the first side surface and the second side surface being located between the first end portion and the second end portion;
a first gate electrode;
a second gate electrode;
a first conductive layer;
a second conductive layer;
a first gate insulating layer provided between the first gate electrode and the first side surface;
a second gate insulating layer provided between the second gate electrode and the second side surface;
a first metal oxide layer provided between the first conductive layer and the first end portion; and
a second metal oxide layer provided between the second conductive layer and the second end portion.

2. The semiconductor device according to claim 1, further comprising:
a third metal oxide layer provided between the first gate electrode and the first gate insulating layer; and
a fourth metal oxide layer provided between the second gate electrode and the second gate insulating layer.

3. The semiconductor device according to claim 1,
wherein the first metal oxide layer includes an oxide of at least one metal element selected from the group consisting of rare earth elements, zinc (Zn), and magnesium (Mg), and
wherein the second metal oxide layer includes an oxide of at least one metal element selected from the group consisting of rare earth elements, zinc (Zn), and magnesium (Mg).

4. The semiconductor device according to claim 1,
wherein a concentration of conductive impurities in the semiconductor layer is substantially uniform.

5. The semiconductor device according to claim 1,
wherein the semiconductor layer comprises an intrinsic semiconductor material.

6. The semiconductor device according to claim 1,
wherein the semiconductor layer has a tensile stress in a direction in which the first end portion and the second end portion are connected to each other.

7. The semiconductor device according to claim 6, further comprising:
a first stress liner layer and a second stress liner layer arranged to compress the semiconductor layer.

8. The semiconductor device according to claim 1, wherein the semiconductor device is a vertical thin film transistor (TFT).

9. The semiconductor device according to claim 1, wherein the first metal oxide layer is arranged to reduce a height of a Schottky barrier between the semiconductor layer and the first conductive layer.

10. The semiconductor device according to claim 1, wherein the second metal oxide layer is arranged to reduce a height of a Schottky barrier between the semiconductor layer and the second conductive layer.

11. The semiconductor device according to claim 2, wherein the semiconductor device comprises a transistor, and wherein the third metal oxide layer and the fourth metal oxide layer are arranged to reduce the threshold voltage of the transistor.

12. The semiconductor device according to claim 2, wherein a thickness of the first metal oxide layer and a thickness of the second metal oxide layer are greater than a thickness of the third metal oxide layer and a thickness of the fourth metal oxide layer.

13. The semiconductor device according to claim 1, wherein a thickness of the first metal oxide layer and a thickness of the second metal oxide layer are greater than or equal to 0.2 nm and less than or equal to 1.5 nm.

14. The semiconductor device according to claim 1, wherein the first gate electrode and the second gate electrode are non-overlapping with the first conductive layer or the second conductive layer in a direction from the first conductive layer to the second conductive layer.

15. The semiconductor device according to claim 1, wherein the semiconductor layer has a conductive impurity concentration of less than or equal to 1×10¹⁵ atoms/cm³.

16. A method of forming a semiconductor device comprising:
forming a semiconductor layer which includes a first side surface, a second side surface facing the first side surface, a first end portion, and a second end portion facing the first end portion, the first side surface and the second side surface being located between the first end portion and the second end portion;
forming a first gate electrode;
forming a second gate electrode;
forming a first conductive layer;
forming a second conductive layer;
forming a first gate insulating layer between the first gate electrode and the first side surface;
forming a second gate insulating layer between the second gate electrode and the second side surface;
forming a first metal oxide layer between the first conductive layer and the first end portion; and
forming a second metal oxide layer between the second conductive layer and the second end portion.
